(19) United States
(12) Patent Application Publication
(10) Pub. No.: US 2025/0004062 A1
(43) Pub. Date: Jan. 2, 2025

(54) METHOD FOR THE DETECTION OF INSULATION FAULTS IN A MOTOR VEHICLE

(71) Applicant: AMPERE S.A.S., Boulogne Billancourt (FR)

(72) Inventor: Houssem HALALCHI, Guyancourt (FR)

(73) Assignee: AMPERE S.A.S., Boulogne Billancourt (FR)

(21) Appl. No.: 18/707,461

(22) PCT Filed: Oct. 24, 2022
(86) PCT No.: PCT/EP2022/079582

§ 371 Date: Jul. 30, 2024

(30) Foreign Application Priority Data
Nov. 4, 2021 (FR) FR2111726

(51) Int. Cl. G01R 31/389; B60L 3/00; G01R 31/3835; H01M 10/42

(52) U.S. Cl. CPC G01R 31/389; G01R 31/3835; H01M 10/4285; B60L 3/0046; H01M 2220/20

(57) ABSTRACT

A method for detecting an insulation fault of an electric battery. The method includes acquiring an insulation resistance value from a detection device, the detection device being connected to an electrical accumulator battery terminal and to ground, and including, in series, a current-limiting resistor, a filtering resistor and a voltage source, and a filtering capacitor in parallel with said filtering resistor. The method further includes a series of steps of optimizing the switching period of the switch of the device for detecting the insulation resistance value.

The invention relates to a method for detecting insulation faults in a motor vehicle.

In the field of the management of electrical accumulator batteries for motor vehicles, it is particularly important to detect a potential insulation fault as quickly as possible.

In particular, in electric or hybrid motor vehicles, the batteries are composed of a succession of blocks of cells placed in series one after another.

Therefore, in order to allow rapid maintenance of the battery, it is relatively important to detect the insulation fault as rapidly as possible and to determine the block of the battery that contains the fault.

Methods and devices for detecting insulation faults based on the measurement of the insulation resistance of the battery are known for this purpose.

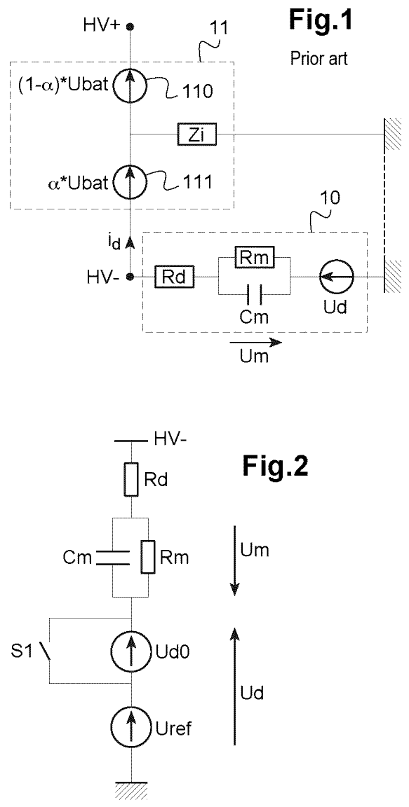

As shown in FIG. 1 from the prior art, a battery 11 is shown in the form of a voltage source 110, 111 and an insulation impedance Zi.

A measuring device 10 for measuring the insulation resistance Ri comprises a current-limiting resistor Rd, a filtering resistor Rm, a filtering capacitor Cm and a voltage source Ud.

This measuring device 10 connected between the lower terminal of the battery 11 and ground makes it possible to determine whether the battery has an insulation fault, and at which location, as a function of a value α calculated as explained below.

Specifically, it is possible to determine a value α that makes it possible to determine the position of the fault in the succession of blocks of cells placed in series one after another.

First of all, a first voltage Ud₁ is applied to the circuit and the voltage Um₁ across the terminals of the resistor Rm is measured.

A second voltage Ud₂ with a different value to the first is then applied and the voltage Um₂ across the terminals of the resistor Rm is measured.

The insulation resistance Ri and the position a of the fault in the battery are then calculated.

Since the capacitive effect is negligible, and considering the total voltage of the battery Ubat to be constant over the two tests the following is obtained in the steady state:

$${R}_{i} = {R}_{m} \cdot \frac{{U}_{d 2} - {U}_{d 1}}{{U}_{m 2} - {U}_{m 1}} - ( {R}_{d} + {R}_{m} ) \qquad ( 1 )$$

$$∝ = \frac{{U}_{m 1} {U}_{d 2} - {U}_{d 1} {U}_{m 2}}{{U}_{bat} \cdot ( {U}_{m 2} - {U}_{m 1} )} \qquad ( 2 )$$

If it is desired to take into account voltage variations in the traction battery Ubat between the two measurements, with Ubat₁ during the first measurement and Ubat₂ during the second measurement, these equations become:

$${R}_{i} = \frac{{R}_{m}}{{U}_{m 2} - {U}_{m 1}} \cdot [ {U}_{d 2} - {U}_{d 1} + \frac{( {U}_{bat 2} - {U}_{bat 1} ) \cdot ( {U}_{m 1} \cdot {U}_{d 2} - {U}_{m 2} \cdot {U}_{d 1} )}{( {U}_{m 2} \cdot {U}_{bat 1} - {U}_{m 1} \cdot {U}_{bat 2} )} ] - ( {R}_{d} + {R}_{m} ) \qquad ( 3 )$$

$$∝ = \frac{{U}_{m 1} {U}_{d 2} - {U}_{d 1} {U}_{m 2}}{{U}_{m 2} \cdot {U}_{bat 1} - {U}_{m 1} \cdot {U}_{bat 2}} \qquad ( 4 )$$

Since the measurement of Um is generally noisy, the equations (1)-(2) or (3)-(4) are not used directly.

They are generally adapted by two recursive least squares (RLS) filters that are designed to provide a stable estimate of each of the two quantities.

These filters iteratively use the successive measurements of the voltage Um in their process of convergence toward the final values of Ri and α.

This measuring device therefore periodically provides an indication of the state of the electrical insulation of the traction system to the supervisor and allows same to take the necessary measures if an insulation fault is observed.

However, such an implementation of the detection of insulation faults is not optimized with respect to its duration of convergence toward the final values of Ri and α.

The document EP3385729B1 describes an analytical method for calculating the optimum switching duration of the power supply circuit. However, such an analytical method certainly lacks reliability, taking into account variations in parameters that are inherent to this type of system.

To this end, the present invention proposes a method for detecting an insulation fault in an electrical accumulator battery, the method being designed to acquire an insulation resistance value from a detection device,

the detection device being connected, on the one hand, to an electrical accumulator battery terminal and, on the other hand, to ground; and comprising, in series, a current-limiting resistor, a filtering resistor and a voltage source, and a filtering capacitor in parallel with said filtering resistor,

said voltage source comprising a permanent source and another source that is able to be activated by a switch that is connected in parallel with the terminals thereof;

the method detecting the insulation fault as a function of an insulation resistance value obtained as a function of the measurements from the current-limiting resistor, the filtering resistor and the filtering capacitor; these measurements being obtained for two separate values of the voltage source acquired with a time difference defined by a switching period of the switch.

The method implements a set of steps for optimizing the switching period and comprises:
a step of initializing the switching period of the switch and a time counter; and in a loop, in successive increments spaced apart by a predetermined duration, the following steps of:
   measuring the voltage across the terminals of the filtering resistor;
   calculating the variation of the voltage measured between the current increment and a preceding increment;
   if said calculated variation is greater than a predetermined threshold value, the time counter is incremented by the predetermined duration; and
   if said calculated variation is lower than said predetermined threshold value, said switching period is then defined as being equal to the value of the time counter.

It is therefore possible to optimize the time for detecting an insulation fault in a battery while implementing a device for detecting an insulation fault.

Advantageously and without limitation, when the variation is lower than said predetermined threshold value, a safety time margin is also added to said switching period.

It is therefore possible to ensure that the duration of convergence is not faster than a potential stabilization duration that would vary slightly between two switching operations of the switch of the measuring device.

Advantageously and without limitation, the set of steps for optimizing the switching period is implemented when the electrical accumulator battery is turned on. It is therefore possible to detect an insulation fault in the battery in a reliable, rapid and permanent manner.

Advantageously and without limitation, the set of steps for optimizing the switching period is implemented when a preliminary step of detecting a potential fault detects the possibility of an insulation fault. It is therefore possible to rapidly confirm suspected detection of an insulation fault in the battery.

In particular, said preliminary step of detecting a potential fault as a function of the estimate of an insulation resistance value acquired from a battery management device on a bidirectional data bus, such as a CAN bus, and as a function of a predefined voltage threshold. This makes it possible to achieve relevant triggering of suspected detection of an insulation fault.

The invention also relates to a device for detecting an insulation fault in an electrical accumulator battery,

connected, on the one hand, to an electrical accumulator battery terminal and, on the other hand, to ground; and comprising, in series, a current-limiting resistor, a filtering resistor and a voltage source, and a filtering capacitor in parallel with said filtering resistor,

said voltage source comprising a permanent source and another source that is able to be activated by a switch that is connected in parallel with the terminals thereof;

said device being designed to measure an insulation resistance value;

the device being designed to detect the insulation fault as a function of an insulation resistance value obtained as a function of the measurements from the current-limiting resistor, the filtering resistor and the filtering capacitor; these measurements being obtained for two separate values of the voltage source acquired with a time difference defined by a switching period of the switch; characterized in that the device comprises means for implementing a set of steps for optimizing the switching period, comprising:
a step of initializing the switching period of the switch and a time counter; and in a loop, in successive increments spaced apart by a predetermined duration, the following steps of:
   measuring the voltage across the terminals of the filtering resistor;
   calculating the variation of the voltage measured between the current increment and a preceding increment;
   if said calculated variation is greater than a predetermined threshold value, the time counter is incremented by the predetermined duration; and
   if said calculated variation is lower than said predetermined threshold value, said switching period is then defined as being equal to the value of the time counter.

The invention also relates to a motor vehicle comprising a device for detecting an insulation fault in an electrical accumulator battery as described above.

Other features and advantages of the invention will become apparent on reading the description given below of one particular embodiment of the invention, given by way of indication but without limitation, with reference to the appended drawings, in which:

FIG. 1 is a schematic view of an electrical accumulator battery and a device for detecting an insulation fault that is known from the prior art;

FIG. 2 is a schematic view of the device for detecting an insulation fault in the battery;

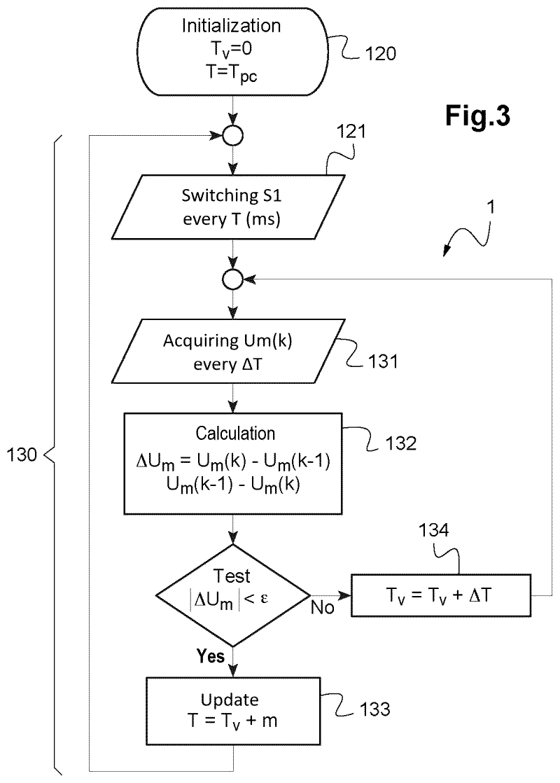

FIG. 3 is a flow chart of a method according to a first embodiment of the invention;

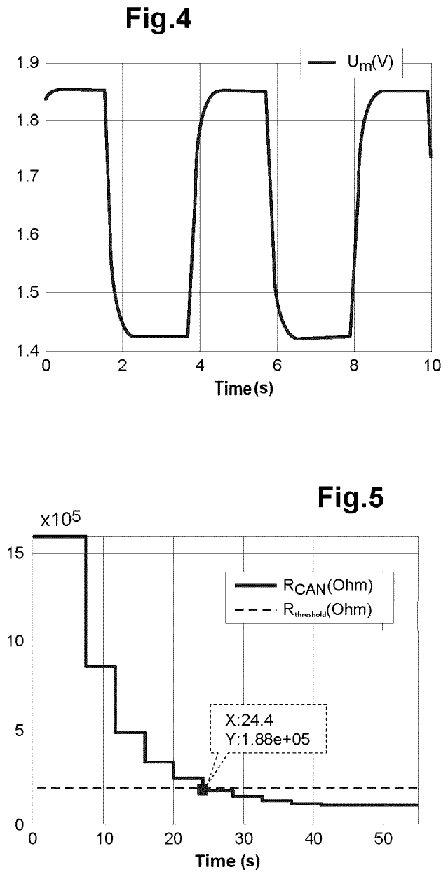

FIG. 4 is a diagram showing the voltage Um measured by the insulation detection device in what is known as a “worst-case” setting of the switching of the switch S1 known from the prior art;

FIG. 5 is a diagram showing the temporal convergence of the estimate of the insulation resistance Rᵢ in the context of a recursive least squares approach in what is known as a “worst-case” setting of the switching of the switch S1 known from the prior art;

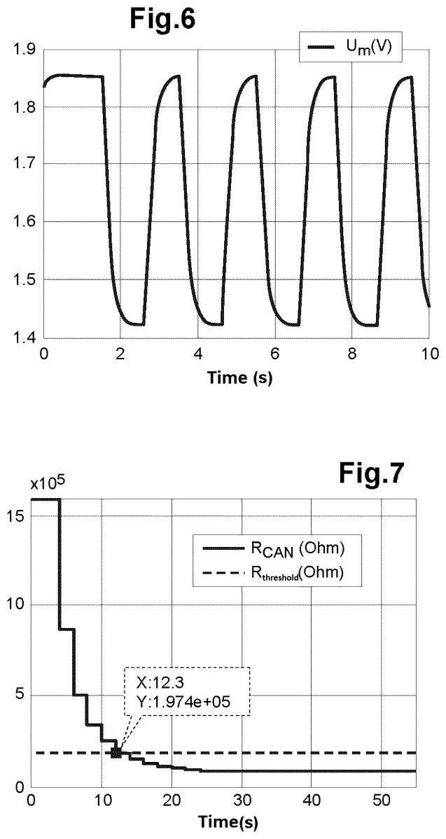

FIG. 6 is a diagram showing the voltage Um measured by the insulation detection device in a setting that is optimized by the method according to the invention;

FIG. 7 is a diagram showing the temporal convergence of the estimate of the insulation resistance Rᵢ in the context of a recursive least squares approach in a setting that is optimized by the method according to the invention; and

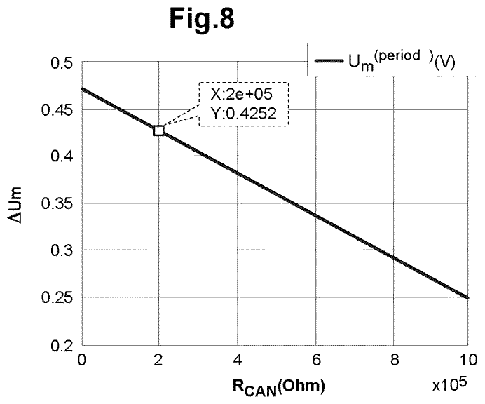

FIG. 8 is a diagram showing the linear relationship between the voltage measured in a CAN (controller area network) data bus as a function of the estimate of the insulation resistance Rᵢ.

The method 1 for detecting an insulation fault in an electrical accumulator battery according to the invention is based on a detection device described above for the prior art.

Specifically, the method 1 according to the invention has the advantage of not needing to structurally modify the detection device 10 for detecting the insulation resistance Ri, which comprises a current-limiting resistor Rd, a filtering resistor Rm, a filtering capacitor Cm and a voltage source Ud.

The control of this device 10 is shown in FIG. 2.

It is necessary to generate two different voltages U_{d1} and U_{d2} to implement the detection of an insulation fault.

The two stable states of the voltage source Ud schematically represented in FIGS. 1 and 2 have the expressions:

$${U}_{d 1} = {U}_{d 0} + {U}_{ref} \qquad ( 5 )$$

$${U}_{d 2} = {U}_{ref} \qquad ( 6 )$$

The switch S1 is switched 121 periodically by the battery management device to take into account, or not, the supply voltage U_{d0}, and consequently obtain the values U_{d1} and U_{d2}, which are used in equations (1) and (2) or (3) and (4).

The duration T of each of the states, defined by the application of either of the values of U_{d}, must be sufficient to make it possible to completely stabilize the measuring circuit and to reach the final value of the measured voltage Uₘ₁ and Uₘ₂.

On account of the recursive nature of the RLS (recursive least squares) filters used, this duration plays an essential role in obtaining the total insulation fault detection duration T_{d}, obeying the formula:

$${T}_{d} = 2 {N}_{d} T \qquad ( 7 )$$

where N_{d} is the number of iterations necessary for the convergence of the RLS filter toward the fault detection threshold. The factor 2 is due to the need to wait for a complete period of switching (opening/closing) of S1 in order to obtain the measurements Uₘ₁ and Uₘ₂ at the end of each state.

The duration T of a state of the switch S1 may be controlled in various ways. The only essential condition for having a measurement in the steady state is:

$$T > 5 {τ}_{i} + m \qquad ( 8 )$$

where:
τᵢ=RiCi: is the time constant associated with the insulation impedance.
m: is a margin applied to take into account analog and digital filtering effects that are applied to the measurement.

The simplest setting of the duration T, known from the prior art, consists in taking a constant duration that constitutes a time constant τᵢ, which may be described as worst case, i.e. maximum values of Ri and Ci that allow an insulation fault to be detected:

$${T}_{pc} = 5 {τ}_{i max} + m \qquad ( 9 )$$

This worst-case setting is very robust since it covers all cases of failure that it is desired to detect. However, this robustness is obtained at the expense of a deterioration in performance, in particular the fault detection time governed by equation (7).

Instead of the worst case, the invention implements a method making it possible to adjust the duration T to the actual dynamics of the electrical circuit by detecting when the latter has reached the steady state.

Therefore, in order to reduce the duration it takes for the method to converge toward a reliable estimate of the existence of an insulation fault, steps are implemented that make it possible to optimize the switching period of the controlled switch S1.

Specifically, in order to calculate the insulation resistance Ri and the position alpha, it is necessary to switch the switch S1 a plurality of times with a calculated period T.

In order to optimize this switching period, the method 1 implements a set of steps for optimizing the switching period T comprising, first of all, a step 120 of initializing the switching period T of the switch S1.

This switching period may, for example, be initialized to a value of 2 seconds.

A time counter Tv is also started up.

The method 1 then implements, in the form of a loop 130, at regular intervals, spaced apart by a predetermined duration Δ_{T}, for example initialized to 100 ms in this case.

In each iteration of the loop:
the voltage Uₘ across the terminals of the filtering resistor Rₘ is measured 131.

The variation of the voltage measured across the terminals of the resistor Rₘ between the preceding iteration of the loop (therefore at t-Δ_{T}) and the measurement of the current iteration is then calculated 132.

A variation value ΔUₘ of the resistance Rm over a duration of Δ_{T} is therefore obtained.

If this variation is greater than a predetermined threshold value, then the time counter Tv is incremented 134 by the predetermined duration Δ_{T}.

If this variation is lower than or equal to this threshold value, the leakage resistance value is considered to have converged toward a stable value. The switching period T is therefore defined 133 as being equal to the value of the time counter Tv.

The loop 130 is then restarted for the following iteration, ensuring that the time between two iterations Δ_{T} is reached.

Since, in parallel, the switching operations of the switch S1 continue with this time interval T, it is therefore the new value of this time interval that will be taken into account, which allows optimized convergence for implementing the method for detecting the fault and the position of the fault in the electrical accumulator battery.

This method was implemented experimentally, by simulating the system for detecting insulation faults with the following parameter values:

R_{d}=2.1 MΩ, Rₘ=17 kΩ, U_{d0}=58.48V, U_{ref}=4.096V.

In this implementation of the invention, the capacitive effect Cm is not directly applied as shown in the diagram of FIG. 2, but in the form of a double RC filter having a cut-off frequency of 200 Hz.

The detection method is parameterized in the following way:

ε=10 mV is the measurement stabilization detection threshold and m=300 ms, which is a margin that takes filtering and digital processing into account.

An insulation fault at the limit of the fault detection requirement is applied to the battery: Ri=199.9 kOhm and Ci=1.5 μF are produced at the initial instant t=0.

The worst-case setting of the switching duration is defined for the initialization of the switching value: T=Tpc=2000 ms.

The pairs of FIGS. 4-5 and 6-7 show the detection results obtained with a constant worst-case setting of the switching duration and an optimized setting of this duration, respectively.

FIG. 7 illustrates the voltage measured with an optimized setting; it is therefore possible to note that the first complete switching operation stops when stabilization is detected, with a duration of Tv=600 ms.

Adding the safety margin m=300 ms results in a switching time of T=Tv+m=900 ms, which is applied for the following switching operations.

FIG. 7 shows the saving in time for detecting a fault that is obtained on account of the optimized setting. This detection time Td therefore changes from 24.4 seconds (in the non-optimized case shown in FIG. 5) to 12.3 seconds, i.e. a reduction of substantially 50%.

This saving is explained by equation (7) that shows a proportionality relationship between the switching time of the switch T and the fault detection time Td, with a number of iterations Nd=6 for the convergence of the RLS algorithm.

The method 1 according to the invention may be activated according to two main criteria, which relate to two main modes of operation of the invention:
insulation fault detection mode that is implemented when the method is active from the start of the vehicle mission. In this case, the objective is to detect a potential fault without providing a precise insulation resistance measurement.
insulation resistance measurement mode, implemented when the method is triggered upon detecting an event, the duration of the state of the switch keeping its maximum value outside of this event. This makes it possible to obtain an estimate that is relatively precise for high values of insulation resistance, and to promote speed of detection by triggering the duration optimization algorithm when a fault is detected.

In other words, in this second mode, the optimization method 1 is triggered only when an insulation fault is suspected.

For the purpose of detecting this event, the electric vehicle supervisor, known by the abbreviation HEVC, detects the suspected insulation fault, which is also referred to as an event, by comparing the estimate of the insulation resistance R_{CAN} sent to it by the battery management device, known as BMS, on the bidirectional data bus, known as CAN bus, with a predefined threshold R_{threshold}.

It is possible to obtain, to a first approximation:

$${R}_{CAN} = {R}_{i} / {R}_{d} \qquad ( 10 )$$

The system then estimates that an insulation fault is detected if:

$${R}_{CAN} < {R}_{threshold} \qquad ( 11 )$$

By combining the constraint of the inequality (11) with the expression of Rᵢ of equation (1), it is possible to deduce a new criterion that is directly based on the variation of the measurement over a complete period of switching of the switch: ΔUₘ^{(period)}=Uₘ₂−Uₘ₁.

$$Δ {U}_{m}^{( period )} > \frac{Δ {U}_{d} {R}_{m}}{\frac{{R}_{threshold} {R}_{d}}{{R}_{d} - {R}_{threshold}} + {R}_{d} + {R}_{m}} = E \qquad ( 12 )$$

where ΔU_{d}=U_{d2}−U_{d1}=U_{d0} is the variation of the supply voltage over one period.

The change in direction of the inequality between the constraints (11) and (12) is due to the inverse proportionality between ΔUₘ^{(period)} and R_{CAN} that is illustrated in FIG. 8, where the values of R_{threshold}=200 kOhm and the corresponding limit value of E=0.4252 V are placed.

It is only when the inequality (12) is verified that the method (1) is activated.

In other words, instead of activating the method for optimizing the switching duration of the switch from the start of the vehicle mission, it is possible to trigger it in the event of an anomaly observed in the measured voltage.

For example, a large difference between the two operating points ΔUₘ^{(period)}=Uₘ₂−Uₘ₁ indicates a low insulation resistance, therefore the potential presence of an insulation fault that should be able to be detected as quickly as possible. The value of this difference may also serve as a criterion for releasing the duration optimization algorithm when a return to normal is detected, for example if ΔUₘ^{(period)}<<E.

In order to place the method 1 according to the invention in parallel with the control of the switching of the switch S by the battery management module, the method may be implemented on a processor core, a separate computer or else an independent thread of the same processor as the one implemented by the battery management module, which is often abbreviated to BMS (battery management system).

1. A method for detecting an insulation fault in an electrical accumulator battery, the method being designed to acquire an insulation resistance value from a detection device,
the detection device being connected to an electrical accumulator battery terminal and to ground, and comprising, in series, a current-limiting resistor, a filtering resistor and a voltage source, and a filtering capacitor in parallel with said filtering resistor,
said voltage source comprising a permanent source and another source that is able to be activated by a switch that is connected in parallel with the terminals thereof;
the method detecting the insulation fault as a function of an insulation resistance value obtained as a function of measurements from the current-limiting resistor, the filtering resistor and the filtering capacitor; the measurements being obtained for two separate values of the voltage source produced periodically by a step of switching the switch; wherein the method implements a set of steps for optimizing a switching period, comprising:
a step of initializing the switching period of the switch and a time counter; and in a loop, in successive increments spaced apart by a predetermined duration, the following steps of:
measuring the voltage across the terminals of the filtering resistor;
calculating variation of the voltage measured between the current increment and a preceding increment;
if said calculated variation is greater than a predetermined threshold value, the time counter is incremented by the predetermined duration; and
if said calculated variation is lower than said predetermined threshold value, said switching period is then defined as being equal to the value of the time counter.

2. The method as claimed in claim 1, wherein, when the variation is lower than said predetermined threshold value, a safety time margin is also added to said switching period.

3. The method as claimed in claim 1, wherein the set of steps for optimizing the switching period is implemented when the electrical accumulator battery is turned on.

4. The method as claimed in claim 1, wherein the set of steps for optimizing the switching period is implemented when a preliminary step of detecting a potential fault detects possibility of an insulation fault.

5. The method as claimed in claim 4, wherein said preliminary step of detecting a potential fault as a function of an estimate of an insulation resistance value acquired from a battery management device on a bidirectional data bus, and as a function of a predefined voltage threshold.

6. A device for detecting an insulation fault in an electrical accumulator battery,
connected to an electrical accumulator battery terminal and to ground, and comprising, in series, a current-limiting resistor, a filtering resistor and a voltage source, and a filtering capacitor in parallel with said filtering resistor,
said voltage source comprising a permanent source and another source that is able to be activated by a switch that is connected in parallel with the terminals thereof;
said device being designed to measure an insulation resistance value,
the device being designed to detect the insulation fault as a function of an insulation resistance value obtained as a function of the measurements from the current-limiting resistor, the filtering resistor and the filtering capacitor; the measurements being obtained for two separate values of the voltage source acquired with a time difference defined by a switching period of the switch;
wherein the device comprises means for implementing a set of steps for optimizing the switching period, comprising:
a step of initializing the switching period of the switch and a time counter; and in a loop, in successive increments spaced apart by a predetermined duration, the following steps of:
measuring the voltage across the terminals of the filtering resistor;
calculating variation of the voltage measured between the current increment and a preceding increment;
if said calculated variation is greater than a predetermined threshold value, the time counter is incremented by the predetermined duration; and
if said calculated variation is lower than said predetermined threshold value, said switching period is then defined as being equal to the value of the time counter.

7. A motor vehicle comprising the device for detecting the insulation fault in the electrical accumulator battery as claimed in claim 6.
